(19) United States
(12) Patent Application Publication
(10) Pub. No.: US 2022/0384359 A1
(43) Pub. Date: Dec. 1, 2022

(54) COMPOSITE STRUCTURE AND PACKAGE ARCHITECTURE

(71) Applicant: Deep Thermal Technology Corporation, Taipei City (TW)

(72) Inventor: Lung-Yu Chang, Taipei City (TW)

(73) Assignee: Deep Thermal Technology Corporation, Taipei City (TW)

(21) Appl. No.: 17/749,150

(22) Filed: May 20, 2022

(30) Foreign Application Priority Data
May 31, 2021 (TW) 110119615

(51) Int. Cl. H01L 23/552; H01L 23/373; H01L 23/473

(52) U.S. Cl. CPC H01L 23/552; H01L 23/3731; H01L 23/473

(57) ABSTRACT

A composite structure includes a first metal layer, a second metal layer, and a ceramic layer disposed therebetween. The ceramic layer has a first surface and a second surface opposite to each other and is adapted to absorb electromagnetic waves. The absorbance reaction range of the electromagnetic waves by the ceramic layer ranges from 100 MHz to 400 GHz. The first metal layer has an opening exposing the second surface. An inner sidewall of the first metal layer surrounds the opening. The orthographic projection of the second metal layer on the ceramic layer at least partially overlaps the orthographic projection of the opening on the ceramic layer. The thickness ratio of the first metal layer to the second metal layer is 1:1 to 1:2. The area ratio of the first metal layer to the second metal layer is 1:1.2 to 1:4. A package architecture including the composite structure is also provided.

### CROSS-REFERENCE TO RELATED APPLICATION

This application claims the priority benefit of Taiwan application serial no. 110119615, filed on May 31, 2021. The entirety of the above-mentioned patent application is hereby incorporated by reference herein and made a part of this specification.

### BACKGROUND

### Technical Field

The disclosure relates to a composite layer and a package including the same, particularly to a composite structure for heat dissipation and noise absorption and a package architecture including the same.

### Description of Related Art

The operating frequency and the speed of electronic components like processors have been improving along with the ongoing development in the electronic information industry. However, as electronic components operate at high frequency and high speed, heat increases significantly, bringing the temperature higher, and more electromagnetic noise interference is generated. These factors in turns compromise the performance of the electronic components during their operation. Problems like heat and electromagnetic noise interference affecting electronic components must be tackled to ensure normal functioning of the electronic components.

Since heat and electromagnetic interference emitted by the existing electronic components are getting severer, it is imperative in this field to come up with a package architecture with good heat dissipation and electromagnetic noise reduction.

### SUMMARY

The present disclosure provides a composite structure with good heat dissipation and electromagnetic wave absorption.

The disclosure provides a package architecture with good heat dissipation, electromagnetic noise reduction, and good electronic performance and quality.

The composite structure of the disclosure includes a first metal layer, a ceramic layer, and a second metal layer. The ceramic layer has a first surface and a second surface opposite to each other. The ceramic layer is suitable for absorbing electromagnetic waves, and the absorbance reaction range of the electromagnetic waves by the ceramic layer ranges from 100 MHz to 400 GHz. The first metal layer is disposed on the second surface. The first metal layer has an opening, and the opening exposes the second surface of the ceramic layer. The inner sidewall of the first metal layer surrounds the opening. The second metal layer is disposed on the first surface. The orthographic projection of the second metal layer on the ceramic layer at least partially overlaps the orthographic projection of the opening on the ceramic layer. The ceramic layer is disposed between the first metal layer and the second metal layer. The thickness ratio of the first metal layer to the second metal layer ranges from 1:1 to 1:2. The area ratio of the first metal layer to the second metal layer ranges from 1:1.2 to 1:4.

The package architecture of the disclosure includes a substrate, a composite structure, and a chip. The composite structure is disposed on the substrate, and an accommodation space is formed between the composite structure and the substrate. The composite structure includes a ceramic layer, a first metal layer, and a second metal layer. The ceramic layer has a first surface and a second surface opposite to each other. The ceramic layer is suitable for absorbing electromagnetic waves. The ceramic layer has a groove, and the groove overlaps the accommodation space. The first metal layer is disposed on the second surface, and has an opening exposing the second surface of the ceramic layer. The inner sidewall of the first metal layer surrounds the opening. The second metal layer is disposed on the first surface. The orthographic projection of the second metal layer on the ceramic layer at least partially overlaps the orthographic projection of the opening on the ceramic layer. The chip is disposed on the substrate and is located in the accommodation space. The chip is coupled to the ceramic layer of the composite structure in the groove. The thermal expansion coefficient of the chip matches the thermal expansion coefficient of the ceramic layer of the composite structure.

Based on the above, in the composite structure and the package architecture including the same according to an embodiment of the disclosure, since the composite structure includes a ceramic layer that absorbs electromagnetic waves and that the first metal layer and the second metal layer are on both surfaces of the ceramic layer, the composite structure can not only absorb electromagnetic waves, but also reflect external electromagnetic waves. In this way, the composite structure has the technical effects of anti-noise and noise reduction. In addition, the second metal layer may also dissipate the thermal energy transferred by the ceramic layer. Therefore, the composite structure has good heat dissipation and electromagnetic wave absorption at the same time. In addition, since the thermal expansion coefficient of the ceramic layer may match the thermal expansion coefficient of the chip, the variation difference between the chip and the ceramic layer may be reduced and warpage may be reduced, such that the package architecture is more reliable. Therefore, the package architecture adopting the composite structure may have good heat dissipation, electromagnetic noise reduction, and good electronic performance and quality.

### BRIEF DESCRIPTION OF THE DRAWING

FIG. 1 is a schematic cross-sectional view of a package architecture according to an embodiment of the disclosure.

FIG. 2 is a schematic cross-sectional view of a package architecture according to another embodiment of the disclosure.

FIG. 3 is a schematic cross-sectional view of a package architecture according to another embodiment of the disclosure.

FIG. 4 is a schematic cross-sectional view of a package architecture according to yet another embodiment of the disclosure.

FIG. 5 is a schematic cross-sectional view of a package architecture according to still another embodiment of the disclosure.

FIG. 6 is a schematic cross-sectional view of a microstructure according to an embodiment of the disclosure.

### DESCRIPTION OF THE EMBODIMENTS

To make the features and advantages of the disclosure easier to be understood, the following embodiments are described in detail with the reference to drawings as follows. As those skilled in the art would realize, the embodiments may be modified in various different ways without departing from the spirit or scope of the disclosure. For example, the relative sizes, thicknesses, and positions of layers, regions, and/or structures may be reduced or exaggerated for clarity.

The terms “first,” “second,” and the like used in the specification may be used to describe various elements, components, regions, layers and/or sections, to which the disclosure is not limited thereto. These terms are only used to distinguish one element, component, region, layer, or section from another. Thus, the following discussion of a “first element,” “first component,” “first region,” “first layer,” or “first section” is used in conjunction with a “second element,” “second component,” “second region,” “second layer,” or “second section” are not intended to limit these elements to specific elements, components, regions, layers, and/or sections or their order.

Furthermore, the terms “comprising,” “including,” “having,” and the like in this specification are all open-ended terms. In other words, these terms means “including but the not limited thereto.”

In the disclosure, the embodiments described below may be mixed and matched and not depart from the spirit and scope of the disclosure. For example, some features of one embodiment may be combined with some features of another embodiment to form another embodiment.

Reference will now be made in detail to the exemplary embodiments of the disclosure, examples of which are illustrated in the drawings. Wherever possible, the same reference numerals in the drawings and description refer to the same or parts alike. The disclosure may also be embodied in different forms and is not limited to the embodiments described herein. The thickness of regions representing elements or layers in the drawings may be exaggerated for clarity. The detailed description of the same or similar reference numerals referring to the same or parts alike is not repeated. In addition, the directional terms used in the embodiments, such as up, down, left, right, front or rear, only refer to the directions of the drawings. Accordingly, the directional terms used are illustrative and not limiting of the disclosure.

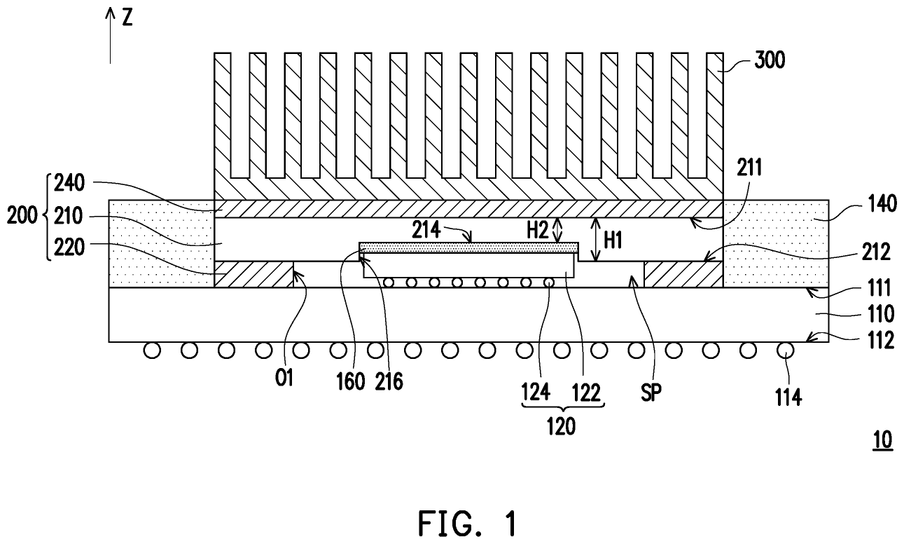

FIG. 1 is a schematic cross-sectional view of a package architecture according to an embodiment of the disclosure. For the clarity of the drawing and the convenience of description, some elements are omitted in FIG. 1. First, in FIG. 1, the package architecture 10 includes a substrate 110, a composite structure 200, and a chip 120. On the Z-axis (i.e., the normal direction of the substrate 110), the composite structure 200 is disposed on the substrate 110. The composite structure 200 is, for example, an inverted U-shaped or a cap-shaped structure, such that an accommodation space SP may be formed between the composite structure 200 and the substrate 110. The chip 120 is disposed on the substrate 110 and located in the accommodation space SP. In embodiments of the disclosure, the chip 120 may be in contact with or adjacent to the composite structure 200. With the configuration described above, the heat generated by the chip 120 during operation may be transferred to the composite structure 200 and be further transferred efficiently to the heat dissipation element 300 and dissipated into the environment. Furthermore, electromagnetic waves or electromagnetic noises generated by the chip 120 during operation may be absorbed by the composite structure 200 to reduce the electromagnetic interference (EMI) in the accommodation space SP, such that the composite structure 200 has the technical effect of electromagnetic noise reduction or anti-electromagnetic noise, such that the electromagnetic noise in the accommodation space SP may be reduced or eliminated. In this way, the risk of the chip 120 subjected to electromagnetic interference in the accommodation space SP may be reduced, or the chip 120 in the accommodation space SP may be kept in a clean environment with no electromagnetic interference. With the configuration described above, the package architecture 10 has good heat dissipation and electromagnetic noise reduction effects. And since the ceramic layer 210 and the metal layers 210 and 220 in the composite structure 200 adopt a direct bonding technology (such as copper-clad ceramics) to reduce the thermal resistance between the film layers in the composite structure 200, the chip 120 is provided with good heat dissipation, and the influence of electromagnetic interference on the chip 120 may be reduced, such that the package architecture 10 has good electronic performance and quality.

Again, in FIG. 1, the substrate 110 of the package architecture 10 is, for example, a rigid substrate, a flexible substrate, or a combination thereof. The substrate 110 includes glass, quartz, sapphire, acrylic resin, polycarbonate (PC), polyimide (PI), polyethylene terephthalate (PET), other suitable transparent materials, or a combination thereof, but the disclosure is not limited thereto. In some embodiments, the substrate 110 is a single-layer or multi-layer structure. For example, the substrate 110 may be a printed circuit board. The substrate 110 is, for example, a structure formed by stacks of circuit layers. Each circuit layer includes, for example, an insulating layer and a conductive layer. The conductive layer includes lines disposed on the surface of the insulating layer and the conductive through holes penetrating the insulating layer. The material of the insulating layer includes the core layer of partially cured resin, such as prepreg (PP), ABF (Ajinomoto Build-up Film) resin, or photo-curable dielectric material (for example, photoimageable dielectric material (PID)), but the disclosure is not limited thereto. Materials for the lines of the conductive layer and the conductive through holes include, for example, copper (Cu), molybdenum (Mo), titanium (Ti), tantalum (Ta), niobium (Nb), hafnium (Hf), nickel (Ni), chromium (Cr), cobalt (Co), zirconium (Zr), tungsten (W), aluminum (Al), silver (Ag), gold (Au), or alloys thereof, but the disclosure is not limited thereto.

The substrate 110 has an upper surface 111 and a lower surface 112 opposite to each other. On the lower surface 112, a plurality of connectors 114 are provided. The connectors 114 may be electrically connected to the circuit layer on the lower surface 112 of the substrate 110. The connectors 114 include, for example, solder balls, microbumps, controlled collapse chip connection (C4) bumps, ball grid array (BGA) balls, or other suitable components, but the disclosure is not limited thereto. The material of the connectors 114 may be the same as the material of the conductive layer, so the description is not repeated here. In some embodiments, the material of the connector 114 also includes tin (Sn).

The chip 120 is disposed on the upper surface 111 of the substrate 110. The chip 120 includes an integrated circuit device 122 and connectors 124. The integrated circuit device 122 may include a logic die, and the logic die may include a central processing unit (CPU) die, graphics processing unit (GPU) die, mobile application die, micro control unit (MCU) die, baseband (BB) die, application processor (AP) die, field-programmable gate array (FPGA) die, application-specific integrated circuit (ASIC) die, or the like. The integrated circuit device 122 may also include a memory die, an input-output (IO) die, or the like. In other embodiments, the chip 120 may also include an integrated passive device (IPD), but the disclosure is not limited thereto. The connectors 124 are connected to the active surface of the integrated circuit device 122 and the circuit layer on the upper surface 111 of the substrate 110, such that the integrated circuit device 122 may be electrically connected to the substrate 110 through the connectors 124. The connectors 124 include, for example, solder balls, microbumps, controlled collapse chip connection (C4) bumps, ball grid array (BGA) balls, or other suitable components, but the disclosure is not limited thereto.

In some embodiments, the chip 120 is, for example, a chip with a radio frequency (RF) communication function. Multiple chips 120 enable wireless communication. Note here that FIG. 1 only shows one chip 120, but the number of chips 120 is not limited thereto. The number of chips may be, for example, 2, 3, 10, or more based on actual design requirements, and the disclosure is not limited thereto.

In the embodiment of the present disclosure, the package architecture 10 may be a single-layer package or a package on package (PoP), but the disclosure is not limited thereto. The package architecture 10 may include a wafer level package (WLP), chip scale package (CSP), system-in-package (SiP), chip-on-Wafer (CoW) structure, chip-on-wafer-on-substrate (CoWoS) structure, or other suitable package, but the disclosure is not limited thereto, such that the package architecture 10 meets the needs of package technology for shrinking electronic components.

The composite structure 200 is disposed on the upper surface 111 of the substrate 110. The composite structure 200 serves as a cap to cover the chip 120, such that the chip 120 may be disposed in the accommodation space between the composite structure 200 and the substrate 110. The chip 120 may contact the composite structure 200 directly or indirectly. With the configuration described above, the thermal energy or electromagnetic waves generated by the chip 120 may be conducted or absorbed by the composite structure to dissipate the heat and reduce the noise. The components and structures of the composite structure 200 are described below in detail.

The composite structure 200 includes a first metal layer 220, a ceramic layer 210, and a second metal layer 240 sequentially stacked on the Z-axis. The ceramic layer 210 is disposed between the first metal layer 220 and the second metal layer 240. The ceramic layer 210 has a first surface 211 (e.g., an upper surface) and a second surface 212 (e.g., a lower surface) opposite to the first surface 211. The first metal layer 220 may have an opening O1 after being patterned, such that the first metal layer 220 has a ring shape with the opening O1 and is disposed on the second surface 212 of the ceramic layer 210. In some embodiments, the first metal layer 220 may be disposed near the outer edge of the ceramic layer 210 and surround the center of the ceramic layer 210. The opening O1 exposes the second surface 212 of the ceramic layer 210, and the inner sidewall of the first metal layer 220 surrounds the opening O1. In other embodiments, the outer edge of the first metal layer 220 may be flush with the outer edge of the ceramic layer 210, but the disclosure is not limited thereto. In some embodiments, the ratio of the area of the first metal layer 220 in contact with the second surface 212 to the area of the second surface 212 ranges from 1:1.2 to 1:10. In some optional embodiments, the area ratio of the first metal layer 220 in contact with the second surface 212 to the area of the second surface 212 ranges from 1:1.2 to 1:4. With the above configuration, the composite structure 200 may have a good anti-noise or noise reduction effect.

In some embodiments, the second metal layer 240 may be entirely disposed on the first surface 211 of the ceramic layer 210. In other words, the second metal layer 240 may completely overlap the ceramic layer 210. The outer edge of the second metal layer 240 may be flush with the outer edge of the ceramic layer 210, but the disclosure is not limited thereto. In some embodiments, the thicknesses of the first metal layer 220 and the second metal layer 240 may be the same or different. For example, the thickness of the first metal layer 220 may be greater than or equal to the thickness of the second metal layer 240, but the disclosure is not limited thereto. In other embodiments, the thickness of the second metal layer 240 may be greater than or equal to the thickness of the first metal layer 220. In some embodiments, the thickness of the first metal layer 220 is 0.05 millimeters (mm) to 0.1 mm. In other embodiments, if the first metal layer 220 is welded to the ceramic layer 210, the thickness of the first metal layer 220 may be 0.1 mm to 0.5 mm, but the disclosure is not limited thereto. If the second metal layer 240 employs a low-power integrated heat spreader (IHS), the thickness of the second metal layer 240 is 0.05 mm to 0.1 mm. In other embodiments, if the second metal layer 240 employs a high-power integrated heat spreader, the thickness of the second metal layer 240 is 0.1 mm to 1.0 mm, but the disclosure is not limited thereto.

In some embodiments, the ratio of the thickness of the first metal layer 220 to the thickness of the second metal layer 240 ranges approximately from 1:1 to 1:2, but the disclosure is not limited thereto. In some optional embodiments, the ratio of the area of the first metal layer 220 to the area of the second metal layer 240 is 1:1.2 to 1:4, but the disclosure is not limited thereto.

In some embodiments, the materials of the first metal layer 220 and the second metal layer 240 may be the same or different, including copper, iron (Fe), molybdenum, titanium, tantalum, niobium, hafnium, nickel, chromium, cobalt, zirconium, tungsten, tin, aluminum, silver, gold, or alloys thereof, but the disclosure is not limited thereto. In this embodiment, the material of the first metal layer 220 and the second metal layer 240 is, for example, copper. The thermal conductivity of the first metal layer 220 or the second metal layer 240 is 100 W/mK to 600 W/mK, or 200 W/mK to 400 W/mK. For example, the thermal conductivity of aluminum is 200 W/mK, and the thermal conductivity of copper is 400 W/mK. With the configuration described above, the first metal layer 220 contacts the substrate 110 and surrounds the chip 120. The second metal layer 240 overlaps the chip 120, such that the chip 120 is located between the second metal layer 240 and the substrate 110. The chip 120 is coupled to the ceramic layer 210. Therefore, the first metal layer 220 and the second metal layer 240 may be employed here in the technology of heat dissipation and electromagnetic shielding to improve the performance of the chip 120.

The ceramic layer 210 is disposed between the first metal layer 220 and the second metal layer 240. The ceramic layer 210 is suitable for absorbing electromagnetic waves generated by the chip 120. In some embodiments, the material of the ceramic layer 210 includes, for example, ferrite. Ferrites are, for example, non-conductive sub-body magnetic ceramic materials comprising iron oxide as its main component. In some embodiments, the bulk material of the ceramic layer 210 includes cubic ferrites, hexagonal ferrites, or orthorhombic ferrites.

The chemical formula of the cubic ferrite is MFe₂O₄, in which Fe is trivalent, whereas M includes divalent nickel (Ni), manganese (Mn), magnesium (Mg), zinc (Zn), copper (Cu), cobalt (Co), or a combination thereof. In addition, the chemical formula of the cubic ferrite may also be R₃Fe₅O₁₂, in which Fe is ferric iron, and R is a rare earth element including yttrium (Y) and lanthanide metals. The lanthanoid metals include, for example, lanthanum (La), cerium (Ce), pyridine (Pr), neodymium (Nd), strontium (Pm), samarium (Sm), europium (Eu), strontium (Gd), strontium (Tb), dysprosium (Dy), holmium (Ho), erbium (Er), tin (Tm), ytterbium (Yb), and tungsten (Lu). In some optional embodiments, R is yttrium or gadolinium, but the disclosure is not limited thereto. In some embodiments, the ferrites may be manganese zinc ferrites (Mn—Zn ferrites), nickel zinc ferrites (Ni—Zn ferrites), or magnesium zinc ferrites (Mg—Zn ferrites), but the disclosure is not limited thereto.

The chemical formula of the mentioned hexagonal ferrite may include BaFe₁₂O₁₉, Ba₂MFe₁₂O₂₂, BaM₂Fe₁₆O₂₇, Ba₃M₂Fe₂₄O₄₁, Ba₂M₂Fe₂₈O₄₆, or Ba₄M₂Fe₃₆O₆₀, in which M is divalent nickel (Ni), cobalt (Co), zinc (Zn) or magnesium (Mg), and barium (Ba) may be substituted by strontium (Sr) or lead (Pb).

The chemical formula of the orthorhombic ferrite may include RFeO₃, in which R is a trivalent rare earth element, and Fe is ferric iron that may be partially substituted by trivalent nickel (Ni), manganese (Mn), chromium (Cr), cobalt (Co), aluminum (Al), calcium (Ca), or pentavalent vanadium (V⁵⁺).

The materials of the ferrites in the embodiments of the disclosure are listed below, but the disclosure is not limited thereto: Fe₃O₄, Ni:B/Fe₃O₄, (Ni_{0.5}Zn_{0.5}) Fe₂O₄, (Ni_{0.4}Cu_{0.2}Zn_{0.4}) Fe₂O₄, (Ni_{0.4}Co_{0.2}Zn_{0.4}) Fe₂O₄, Ni_{0.8}Co_{0.2}Fe₂O₄, Ni_{0.5}Co_{0.5}Fe₂O₄, MnFe₂O₄, Co_{0.5}Mn_{0.5}Fe₂O₄, CoFe₂O₄, Bi_{0.8}La_{0.2}FeO₃, PANI|Co_{0.5}Zn_{0.5}Fe₂O₄, PANI|Li_{0.35}Zn_{0.3}Fe_{2.35}O₄, Nd/BiFeO₃, CoBaTiFe₁₀O₁₉, Ni_{0.4}Co_{0.6}BaTiFe₁₀O₁₉, Ni_{0.2}Co_{0.8}BaTiFe₁₀O₁₉, (MnNi)_{0.2}Co_{0.6}BaTiFe₁₀O₁₉, (MnNi)_{0.25}Co_{0.5}BaTiFe₁₀O₁₉, ZnO/BaFe₁₂O₁₉, BaCe_{0.05}Fe_{11.95}O₁₉, NiFe₂O₄/ZnFe₂O₄/SrFe₁₂O₁₉, (Mn_{0.5}Cd_{0.5}Zr)_{1.4}SrFe_{9.2}O₁₉, (Mn_{0.5}Cd_{0.5}Zr)_{1.6}SrFe_{8.8}O₁₉, Nd_{0.2}Co_{0.2}Sr_{0.8}Fe_{11.8}O₁₉, CoZnAl_{0.2}Ce_{0.2}BaFe_{15.6}O₂₇, Zn_{1.5}Co_{0.5}BaFe₁₆O₂₇, Ba₁CO_{0.9}Zn_{1.1}Fe₁₆O₂₇, Ba_{0.8}La_{0.2}Co_{0.9}Zn_{1.1}Fe₁₆O₂₇, (Sb:SnO₂)|Zn:Co:Gd/BaFe₁₆O₂₇.

In some embodiments, the thermal conductivity of the ceramic layer 210 is 1 W/mK to 25 W/mK. For example, in ferrites, as the proportion of Fe²⁺ to the whole composition is high, the thermal conductivity may be increased to about 25 W/mK. In some embodiments, the thermal conductivity of the ceramic layer 210 is 1 W/mK to 25 W/mK, but the disclosure is not limited thereto. In other embodiments, the thermal conductivity of the ceramic layer 210 may be optionally 1 W/mK to 20 W/mK, but the disclosure is not limited thereto. In this way, the ceramic layer 210 with the function of thermal conduction can transfer the thermal energy generated by the chip 120 to the second metal layer 240 to dissipate the heat.

It should be noted that the thermal expansion coefficient (CTE) of the ceramic layer 210 is 2×10⁻⁶° C. to 12×10⁻⁶° C., but the disclosure is not limited thereto. The chip 120 is, for example, a silicon chip, and its thermal expansion coefficient is 2×10⁻⁶° C. to 3×10⁻⁶° C. With the configuration described above, the thermal expansion coefficient of the chip 120 matches the thermal expansion coefficient of the ceramic layer 210. In the embodiments of the disclosure, the description of “match” or “matching” may be defined as the difference in thermal expansion coefficients between the two elements being less than 10×10⁻⁶° C. Compared with the thermal expansion coefficient of the metal layer (for example, the thermal expansion coefficient of copper is 16.5×10⁻⁶° C.), the thermal expansion coefficient of the chip 120 is similar to that of the ceramic layer 210; however, the volume change of the chip 120 at a high temperature may be similar to the volume change of the ceramic layer 210 in contact therewith. In a preferred embodiment, the thermal expansion coefficient of the ceramic layer 210 may optionally be about 5×10⁻⁶° C. Within the above range, the thermal expansion coefficient of the ceramic layer 210 matches several semiconductor materials, including silicon carbide (SiC), silicon (Si), gallium arsenide (GaAs), gallium nitride (GaN), or other suitable semiconductor materials, to which the disclosure is not limited. Therefore, the variation difference between the chip 120 and the ceramic layer 210 may be reduced and warpage may be reduced, such that the bonding strength between the chip 120 and the ceramic layer 210 of the composite structure 200 may be improved, which makes it more reliable.

In some embodiments, the ceramic layer 210 has a groove 216. The groove 216 may have a depth formed on the second surface 212 of the ceramic layer 210. The groove 216 may overlap the accommodation space SP. In some embodiments, the groove 216 may be located in the outer contour of the accommodation space SP. The groove 216 has a bottom surface 214 and an inner sidewall surrounding the bottom surface 214. There is a height difference between the bottom surface 214 of the groove 216 and the second surface 212 that defines the depth of the groove 216. For example, on the Z-axis, the maximum distance from the second surface 212 to the first surface 211 is the first height H1 (which may be regarded as the thickness of the ceramic layer 210). On the Z-axis, the maximum distance from the bottom surface 214 of the groove 216 to the first surface 211 is the second height H2. In the embodiment, the depth of the groove 216 is defined as the difference between the first height H1 and the second height H2. The first height H1 is, for example, 0.1 mm to 1.0 mm, whereas the second height H2 is, for example, 0.05 mm to 0.9 mm, such that the depth of the groove 216 is, for example, 0.05 mm to 0.1 mm, but the disclosure is not limited thereto.

As shown in FIG. 1, the chip 120 may be disposed corresponding to the groove 216. On the Z-axis, the outer edge of the chip 120 may be within the inner sidewall of the groove 216, but the disclosure is not limited thereto. In some embodiments, the inner sidewall of the groove 216 and the sidewall of the outer edge of the chip 120 may be spaced apart laterally. The passive side of the chip 120 (i.e., the upper surface of the chip 120 in FIG. 1) may contact the ceramic layer 210 in the groove 216, but the disclosure is not limited thereto. With the configuration described above, the chip 120 may have a good effect in heat dissipation by being in contact with the ceramic layer 210 of the composite structure 200. Due to the bonding technology adopted by the ceramic layer 210, the first metal layer 220, and the second metal layer 240 in the composite structure 200, the thermal resistance between the film layers in the composite structure 200 should be reduced to provide good heat dissipation for the chip 120. Low thermal resistant ceramics-metal bonding technology includes direct and indirect bonding. Direct bonding includes direct bonded copper technology, whereas indirect bonding includes brazing and soldering, but the disclosure is not limited thereto.

In some embodiments, a thermally conductive material layer 160 may also be disposed in the groove 216. The thermally conductive material layer 160 is disposed on the bottom surface 214 of the groove 216 of the ceramic layer 210. The thermally conductive material layer 160 is disposed between the chip 120 and the bottom surface 214 of the ceramic layer 210 to connect the chip 120 and the ceramic layer 210. The thermally conductive material layer 160 is, for example, a thermal interface material (TIM), including thermal paste or solder. When the thermally conductive material layer 160 is a thermal paste, the thermal conductivity may be smaller than that of the ceramic layer 210. When the thermally conductive material layer 160 is solder, the thermal conductivity may be greater than or equal to that of the ceramic layer 210. The thermally conductive material layer 160 reduces the contact thermal resistance between the chip 120 and the ceramic layer 210 to improve the heat dissipation. The material of the thermally conductive material layer 160 is, for example, silicone grease, silicone glue, thermally conductive adhesive, or heat dissipation pad. In some embodiments, the material of the thermal paste includes silver paste, solder paste, and aluminum paste. The material of the solder includes glass fiber, acrylic resin or epoxy resin doped with metal particles, or a combination thereof, but the disclosure is not limited thereto.

Notably, the ceramic layer 210 is suitable for absorbing transmitted waves of electromagnetic waves. Generally, when the electromagnetic waves are incident on the ceramic layer 210, part of the waves is reflected, which is called a reflected wave, while the other part is incident on the ceramic layer 160, and the electromagnetic waves incident into the ceramic layer 160 is defined as a transmitted wave. In some embodiments, the absorbance reaction range of the ceramic layer 210 to the electromagnetic waves as mentioned ranges from 100 MHz to 400 GHz. Most of the electromagnetic waves entering the ceramic layer 210 from the second surface 212 of the ceramic layer 210 are absorbed by the ceramic layer 210, and this causes the electromagnetic wave energy (i.e., the transmitted wave) that penetrates the ceramic layer 210 detected on the first surface 211 to be lost, which is called the insertion loss. The insertion loss of electromagnetic waves is shown in Equation 1 as follows:

S₂₁=electromagnetic wave energy measured at the second port/electromagnetic wave energy measured at the first port Equation 1

Here, S₂₁ is the insertion loss of the electromagnetic wave. The first port is the second surface 212 of the ceramic layer 210, and the second port is the first surface 211 of the ceramic layer 210. The electromagnetic wave energy measured at the first port is the electromagnetic wave energy incident on the ceramic layer 210 on the second surface 212, and the electromagnetic wave energy measured at the second port is the electromagnetic wave energy emitted from the ceramic layer 210 on the first surface 211. And this is how the electromagnetic waves absorbed by the ceramic layer 210 may be measured.

The ceramic layer 210 of the composite structure 200 of the embodiment of the present disclosure has a good absorption effect on electromagnetic waves with an absorbance reaction range of 100 MHz to 400 GHz. For example, when a ceramic layer 210 made of manganese-zinc ferrites (Mn—Zn ferrites), nickel-zinc ferrites (Ni—Zn ferrites), or magnesium-zinc ferrites (Mg—Zn ferrites) with a thickness about 4 mm is provided, the range of the insertion loss of electromagnetic waves having a frequency of 1 GHz to 20 GHz is −2 dB to −15 dB. With the configuration described above, the electromagnetic waves emitted by the chip 120 may be absorbed by the ceramic layer 210. The absorbed electromagnetic waves may be transmitted along the ceramic layer 210 to the first metal layer 220, and then be transmitted through the lines on the upper surface 111 of the substrate 110 and the conductive through holes of the conductive layer to the connectors 114 on the lower surface 112 to be grounded. Since the ceramic layer 210 of the composite structure 200 has the effect of absorbing electromagnetic waves to reduce electromagnetic noise, and that the first metal layer 220 and the second metal layer 240 of the composite structure 200 may also surround or cover the chip 120 to reflect electromagnetic waves from the external environment to reduce the electromagnetic noise, the accommodation space SP where the chip 120 is located maintains a clean environment with no electromagnetic interference. With the configuration described above, the package architecture 10 including the composite structure 200 enables the chip 120 to perform wired or wireless communication in the accommodation space with good communication quality. In this way, the package architecture 10 reduces the influence of electromagnetic interference for the chip 120, and with the technology provided by the chip 120 that transmits signals through the wireless communication, the electronic performance and quality of the package architecture 10 are further improved.

In short, as the composite structure 200 includes the ceramic layer 210 that absorbs electromagnetic waves and the first metal layer 220 and the second metal layer 240 disposed on the two surfaces 211 and 212 of the ceramic layer 210, the composite structure 200 not only absorbs electromagnetic waves but also reflects external electromagnetic waves. Therefore, the composite structure 200 has the technical effects of anti-noise and noise reduction, and the influence of electromagnetic noise may be reduced in the accommodation space SP between the composite structure 200 and the substrate 110. In addition, as the ceramic layer 210 of the composite structure 200 are bonded with the first metal layer 220 and the second metal layer 240 using the bonding technology, the composite structure 200 has a good bonding interface thermal resistance to enable the heat energy to be transferred rapidly to the low-temperature fin area of the heat dissipation component 300 to dissipate the heat. Therefore, the ceramic layer 210 of the embodiment of the present disclosure that has the effects of heat dissipation and anti-electromagnetic noise or magnetic noise reduction can dissipate the thermal energy transmitted by the ceramic layer 210 and reduce the influence of electromagnetic waves effectively. Therefore, the composite structure 200 has a good heat dissipation effect and a good electromagnetic wave absorption effect at the same time. In this light, the composite structure 200 may be employed in the package architecture 10 to provide good heat dissipation, electromagnetic noise reduction, and good electronic performance and quality.

In some embodiments, the package architecture 10 further includes a heat dissipation component 300 disposed on the second metal layer 240 of the composite structure 200. The composite structure 200 is located between the heat dissipation component 300 and the substrate 110. The heat dissipation component 300 is, for example, a heat dissipation fin or a heat dissipation block. In some embodiments, the heat dissipation component 300 may also be a heat pipe, but the disclosure is not limited thereto. Therefore, the thermal energy generated by the chip 120 may be transferred to the second metal layer 240 through the ceramic layer 210, and be further dissipated into the environment through the heat dissipation assembly 300, so as to enhance the heat dissipation effect of the package architecture 10 and improve the electronic performance or quality.

In some embodiments, the package architecture 10 further includes a package component 140 disposed on the upper surface 111 of the substrate 110. The package component 140 encapsulates the composite structure 200. For example, the package component 140 may surround composite structure 200. The top surface of the package component 140 may be flush with the top surface of the second metal layer 240, but the disclosure is not limited thereto. The sidewall of the outer edge of the package component 140 may be flush with the sidewall of the outer edge of the substrate 110, but the disclosure is not limited thereto. The material of the package component 140 is, for example, a molding material, including molding compounds, epoxy resins, organic polymers, polymers with or without silica-based fillers or glass fillers, or other materials, but the disclosure is not limited thereto.

With the configuration described above, since the package architecture 10 includes the composite structure 200 that has the effects of heat dissipation and electromagnetic wave absorbance, the package architecture 10 also has the technical effects of heat dissipation, anti-electromagnetic noise, and electromagnetic noise reduction. In addition, the ceramic layer 210 of the composite structure 200 is in contact with the chip 120 to dissipate the heat and reduce the noise. Since the thermal expansion coefficient of the ceramic layer 210 matches the thermal expansion coefficient of the chip 120, the variation difference between the chip 120 and the ceramic layer 210 may be reduced and warpage may be reduced, such that the bonding strength between the chip 120 and the ceramic layer 210 of the composite structure 200 may be improved, which makes it more reliable. In addition, the composite structure 200 may be directly soldered on the chip 120 to increase the heat dissipation efficiency. And the second metal layer 240 also dissipates the heat energy transferred by the ceramic layer 210 through the heat dissipation component 300. Based on the above, the package architecture 10 with the composite structure 200 may have good heat dissipation and electromagnetic noise reduction effects, and good electronic performance and quality.

As the following embodiments adopt the same reference numerals and part of the contents of the previous embodiments, reference may be made to the foregoing embodiments for the descriptions of the same or similar elements with the same reference numerals. The same technical descriptions are not repeated in the following embodiments.

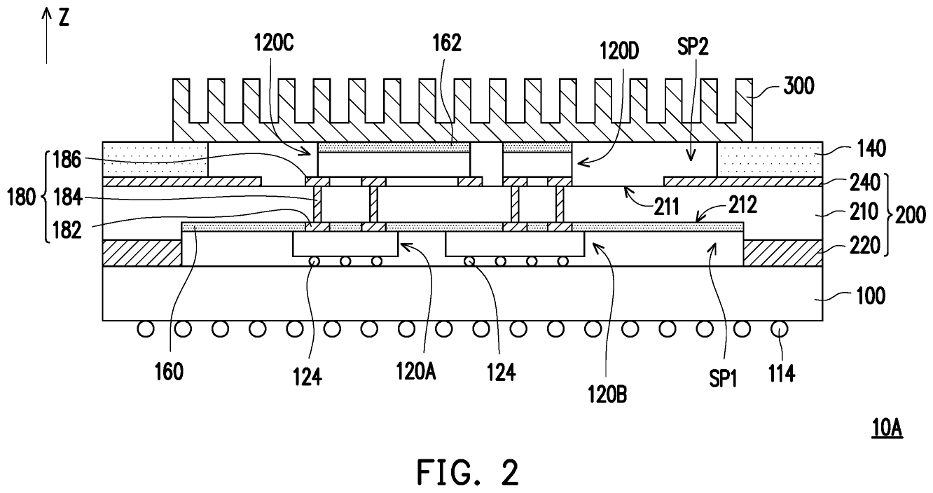

FIG. 2 is a schematic cross-sectional view of a package architecture according to another embodiment of the disclosure. For the clarity of the drawing and the convenience of description, some elements are omitted in FIG. 2. Please refer to FIG. 1 and FIG. 2. The package architecture 10A of this embodiment is similar to the package architecture 10 of FIG. 1, and their main differences are that the composite structure 200 further includes a circuit component 180, and that a plurality of chips 120C and 120D are disposed on the ceramic layer 210 of the composite structure 200. Specifically, the circuit component 180 includes a first circuit pattern 182, a second circuit pattern 186, and a plurality of conductive through holes 184. The first circuit patterns 182 are disposed on the second surface 212 of the ceramic layer 210. The second circuit layer 186 is disposed on the first surface 211 of the ceramic layer 210. The conductive through holes 184 are in the ceramic layer 210, penetrating the ceramic layer 210. The first circuit pattern 182 is, for example, a circuit pattern formed by a patterned conductive material, including circuits and pads. The material of the conductive material is, for example, the same as that of the first metal layer 220 or the second metal layer 240, so the same is not repeated here.

The structure and the material of the second circuit pattern 186 are similar to those of the first circuit pattern 182, and thus the same description is not repeated herein. In some embodiments, the second circuit pattern 186 and the second metal layer 240 belong to the same layer and are formed by the same patterned material layer, but the disclosure is not limited thereto. In some embodiments, the second metal layer 240 at least partially covers the ceramic layer 210. The orthographic projection of the second metal layer 240 on the ceramic layer 210 at least partially overlaps the orthographic projection of the opening O1 on the ceramic layer 210. The first circuit pattern 182 is electrically connected to the second circuit pattern 186 through the conductive through holes 184. In some embodiments, the first circuit layer 182 may be embedded in the thermally conductive material layer 160 or surrounded by the thermally conductive material layer 160, but the disclosure is not limited thereto.

In some embodiments, the first metal layer 220 surrounds the first accommodation space SP1. The package component 140 may be partially disposed on the second metal layer 240 of the composite structure 200, and the heat dissipation component may be disposed on the package component 140 on the ceramic layer 210. The package component 140 may have a ring shape to surround the first surface 211 and define a second accommodation space SP2 with the heat dissipation element 300. On the Z-axis, the first accommodation space SP1 may partially overlap the second accommodation space SP2. In other embodiments, the inner sidewall of the package component 140 may be located within the inner sidewall of the first metal layer 220, but the disclosure is not limited thereto. As shown in FIG. 2, the volume of the first accommodation space SP1 is larger than the volume of the second accommodation space SP2, but the disclosure is not limited thereto.

The package architecture 10A also includes a plurality of chips. The chips include first chips 120A and 120B and second chips 120C and 120D. The first chips 120A and 120B are disposed on the substrate 110 and are located in the first accommodation space SP1. The second chips 120C and 120D are disposed on the ceramic layer 210 of the composite structure 200 and are located in the second accommodation space SP2. The thermally conductive material layer 162 is disposed between the second chips 120C and 120D and the heat dissipation component 300. The thermally conductive material layer 162 and the thermally conductive material layer 160 have the similar structure and similar material, and the same description is not repeated here. In some embodiments, the sidewalls of the thermally conductive material layer 162 are aligned with the sidewalls of the second chips 120C and 120D, but the disclosure is not limited thereto.

The backsides (e.g., the upper surfaces) of the first chips 120A and 120B have contacts or pads to be electrically connected to the first circuit patterns 182 under the ceramic layer 210. The active surfaces (e.g., the lower surfaces) of the second chips 120C and 120D have contacts or pads to be electrically connected to the second circuit patterns 186 on the ceramic layer 210. In this light, the first chips 120A and 120B may be disposed in the first accommodation space SP1 between the substrate 110 and the second surface 212 of the ceramic layer 210, and the second chips 120C and 120D may be disposed in the second accommodation space SP2 between the first surface 211 of the ceramic layer 210 and the heat dissipation component 300. The first chips 120A and 120B may be electrically connected to the second chips 120C and 120D through circuit elements. In this way, with the configuration of the composite structure 200, the first accommodation space SP1 becomes a clean environment with no electromagnetic interference, and, with the configuration of the heat dissipation component 300 and the package component 140, the second accommodation space SP2 has the electromagnetic anti-noise and heat dissipation effects. Therefore, chips that need to avoid electromagnetic interference or implement wireless communication may be placed in the first accommodation space SP1, while computing chips that need heat dissipation or chips that are not easily affected by electromagnetic interference may be placed in the second accommodation space. As such, the package architecture 10A has good electronic performance and quality. In addition, the package architecture 10A may also have the same effect as the embodiment mentioned above.

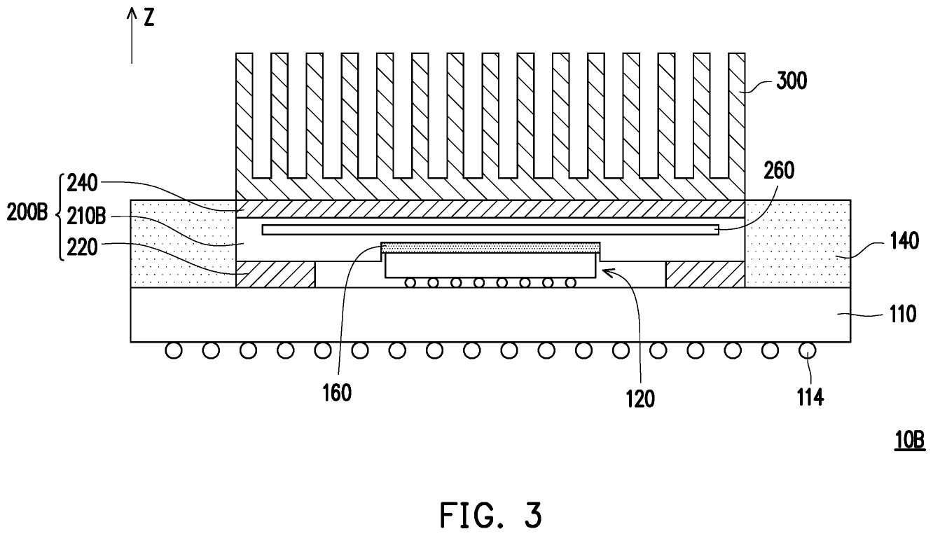

FIG. 3 is a schematic cross-sectional view of a package architecture according to another embodiment of the disclosure. For the clarity of the drawing and the convenience of description, some elements are omitted in FIG. 3. Please refer to FIG. 1 and FIG. 3. The package architecture 10B of the present embodiment is similar to the package architecture 10 of FIG. 1, and their main difference is that the ceramic layer 210B of the composite structure 200B has a sealing space 260. The sealed space 260 is, for example, a groove formed in the ceramic layer 210B and located between the first metal layer 220 and the second metal layer 240. The sealed space 260 is isolated by the ceramic layer 210B. The isolation is defined as a groove in the ceramic layer 210B, which is isolated from the outside by the ceramic layer 210B.

In some embodiments, a working fluid is provided in the sealed space 260 after the sealed space 260 is evacuated. The working fluid is, for example, water, alcohol, ethanol, or other suitable liquids. The volume of the working fluid accounts for about 1:100 to 1:10, or optionally about 1:70 to 1:50, of the volume of the sealed space 260, but the disclosure is not limited thereto. The ratio of the volume of the sealed space 260 to the volume of the ceramic material 210 ranges approximately from 1:1.1 to 1:10, or from about 1:10 to 1:50, but the disclosure is not limited thereto.

With the configuration described above, as the ceramic layer 210B absorbs the thermal energy generated by the chip 120 during operation, the working fluid in the sealed space 260 near the chip 120 may evaporate into gas. Meanwhile, the working fluid in other parts still remains liquid, resulting in a pressure difference. With the pressure difference, the gas approaches the second metal layer 240 on the Z-axis, such that the gas transfers the thermal energy to the second metal layer 240 to be dissipated to the external environment through the heat dissipation component 300. After the gas is cooled into a liquid, it flows back to the heat source in the sealed space 260 near the chip 120. In this way, the composite structure 200B with the sealed space 260 acts as a heat spreader (also referred to as a vapor chamber), which further increases the heat dissipation effect of the composite structure 200B and the package architecture 10B. The package architecture 10B may also achieve the same effect as the above embodiments.

In other embodiments, the sealed space 260 is further provided with a heat-spreading structure for vapor-liquid phase changing. The heat-spreading structure may include a heat pipe or the aforementioned heat spreader, but the disclosure is not limited thereto. In some embodiments, the heat pipe may be embedded in the ceramic layer 210B. The heat pipe is, for example, a hollow metal pipe whose inner hollow space is a closed cavity that contains the working fluid. The working fluid changes between liquid and gas in the cavity as it continuously undergoes vaporization and liquefaction. In this way, the heat pipe further enhances the heat dissipation of the composite structure 200B and the package architecture 10B.

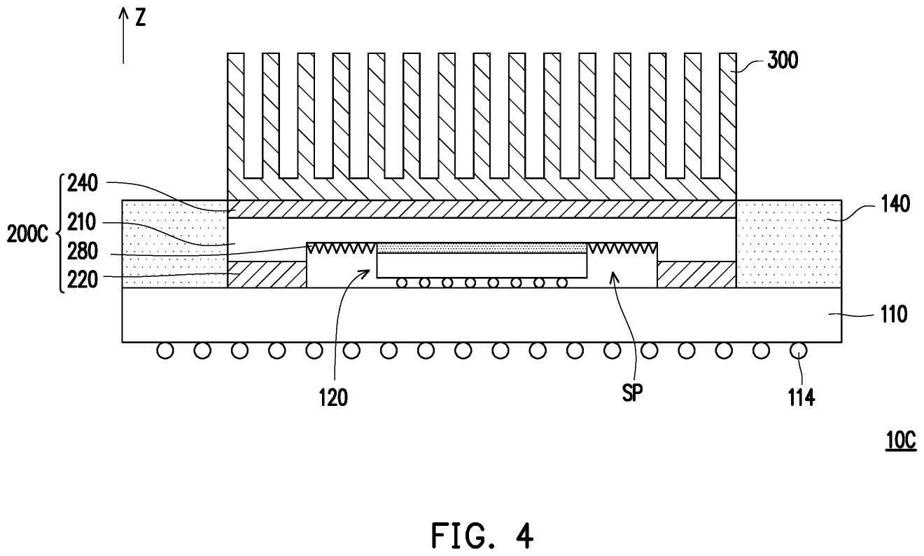

FIG. 4 is a schematic cross-sectional view of a package architecture according to another embodiment of the disclosure. For the clarity of the drawing and the convenience of description, some elements are omitted in FIG. 4. Please refer to FIG. 1 and FIG. 4. The package architecture 10C of the present embodiment is similar to the package architecture 10 of FIG. 1, and their main difference is that the composite structure 200C further includes a plurality of microstructures 280. The microstructures 280 are, for example, cone-shaped structures disposed on the surface of the ceramic layer 210 (e.g., the bottom surface 214 shown in FIG. 1). In other embodiments, the microstructures 280 may also be disposed on the second surface 212 of the ceramic layer 210 shown in FIG. 1. In the embodiment of the disclosure, the microstructures 280 may be triangular pyramids, quadrangular pyramids, pentagonal pyramids or cones, but the disclosure is not limited thereto.

Please refer to FIG. 1 and FIG. 4 at the same time. In FIG. 4, the inner sidewall of the groove 216 of the ceramic layer 210 is flush with the inner sidewall of the first metal layer 220. In other words, the groove 216 overlaps the opening O1. From another perspective, the inner sidewall of the groove 216 is the inner sidewall of the ceramic layer 210. In another embodiment, the part where the ceramic layer 210 overlaps the first metal layer 220 has a first height H1, whereas the part where the ceramic layer 210 does not overlap the first metal layer 220 has a second height H2, as shown in FIG. 4.

In some embodiments, the height of the microstructures 280 is smaller than the depth of the groove 216 defined by the difference between the first height H1 and the second height H2, but the disclosure is not limited thereto. In other embodiments, the height of the microstructures 280 is greater than or equal to the depth of the groove 216.

In some embodiments, the microstructures 280 are laterally spaced from chip 120. In other words, the microstructures 280 are isolated from the chip 120, but the disclosure is not limited thereto. The material of the microstructures 280 includes polymer materials, oxide, nitride, carbide, carbonitride, or graphite, but the disclosure is not limited thereto. The said polymer materials include polyethylene (PE), polyvinyl chloride (PVC), polypropylene (PP), ethylene vinyl acetate (EVA), or other suitable materials, but the disclosure is not limited thereto.

Notably, electromagnetic waves may be incident into the microstructures 280. The refractive index of the electromagnetic waves in the microstructures 280 is greater than the refractive index of the electromagnetic waves in the air, and the refractive index of the electromagnetic waves in the ceramic layer 210 is greater than the refractive index of the electromagnetic waves in the microstructures 280. For example, the refractive index of electromagnetic waves in the microstructures 280 ranges approximately from 1.2 to 2.0, and the refractive index of electromagnetic waves in the ceramic layer 210 ranges approximately from 1.3 to 2.4.

With the above configuration, the electromagnetic waves may be incident into the microstructures 280 from the ambient air and then introduced into the ceramic layer 210. In addition, the electromagnetic waves may be totally reflected in the ceramic layer 210 and between the microstructures 280 and the second metal layer 240, thereby reducing the probability of being reflected back into the accommodation space SP. In this way, the microstructures 280 not only increases the area of the ceramic layer 210 for absorbing electromagnetic waves but also makes the electromagnetic waves travel along the ceramic layer 210, thus increasing the effect of the ceramic layer 210 absorbing electromagnetic waves. In addition, the microstructures 280 may also reduce the probability of the electromagnetic wave reflected back to the accommodation space SP, thereby further improving the noise reduction and anti-noise effects of the composite structure 200C. The composite structure 200C and the package architecture 10C may also achieve the same effect as the above embodiments.

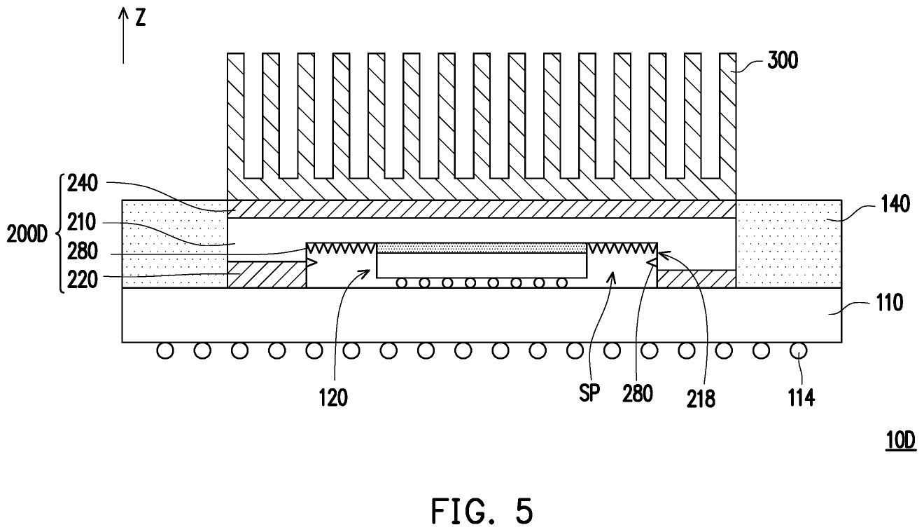

FIG. 5 is a schematic cross-sectional view of a package architecture according to still another embodiment of the disclosure. For the clarity of the drawing and the convenience of description, some elements are omitted in FIG. 5. In FIG. 4 and FIG. 5, the package architecture 10D of this embodiment is similar to the package architecture 10C of FIG. 4, and their main difference is that the microstructures 280 of the composite structure 200D may also be disposed on the sidewalls 218 of the ceramic layer 210. Please refer to FIG. 1, FIG. 4, and FIG. 5. Specifically, the sidewall 218 is the inner sidewall of the groove 216 surrounding the bottom surface 214. From another perspective, the sidewall 218 connects the bottom surface 214 and the second surface 212 (i.e., the surface that contacts the first metal layer 220). Since the microstructures 280 may be disposed on the sidewalls 218 in addition to the bottom surface 214 of the ceramic layer 210, the microstructures 280 further increases the area of the ceramic layer 210 for absorbing electromagnetic waves. In this way, the noise reduction and anti-noise effects of the composite structure 200D may be further improved. The composite structure 200D and the package architecture 10D may also achieve the same effect as the above embodiments.

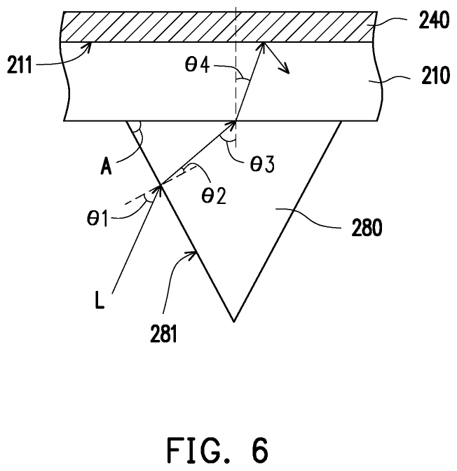

FIG. 6 is a schematic cross-sectional view of a microstructure according to an embodiment of the disclosure. For the clarity of the drawing and the convenience of description, some elements are omitted in FIG. 6. The microstructure 280 shown in FIG. 6 is, for example, the microstructures 280 shown in FIG. 4 or FIG. 5. In some embodiments, the microstructures 280 have, for example, the shape of a cone or a pyramid. The microstructure 280 has an inclined plane 281. The microstructures 280 are disposed on the surface of the ceramic layer 210 (e.g., the bottom surface 214 as shown in FIG. 1). There is an included angle A between the inclined plane 281 and the bottom surface of the ceramic layer 210. The range of the included angle A includes, but not limited to, 30° to 80°. With the above configuration, the inclined plane 281 has a slope, and the slope is in the range of about 0.1 to 10, but the disclosure is not limited thereto. As such, a first incident angle θ1 of the electromagnetic waves L incident into the microstructures 280 may be the largest. The first incident angle θ1 is defined as the angle between the electromagnetic waves L and the normal line of the inclined plane 281.

In some embodiments, the microstructures 280 define a width on the bottom surface of the ceramic layer 210. On the Z-axis, the microstructures 280 may have a height perpendicular to the bottom surface. The width of the microstructures 280 is, for example, 0.2 mm to 2 mm, and the height of the microstructures 280 is, for example, 0.4 mm to 4 mm. The height and width of the microstructures 280 may be used to define the aspect ratio of the microstructures 280, i.e., the ratio of height to width. Therefore, the aspect ratio of the microstructures 280 may be 2:1 to 20:1, but the disclosure is not limited thereto. In some embodiments, if the aspect ratio is too low, the microstructures 280 are less effective in absorbing long-wavelength electromagnetic waves or short-wavelength electromagnetic waves in the communication field.

In other embodiments, two adjacent microstructures 280 are separated by a distance. The distance may be 0.2 mm to 1 mm, but the disclosure is not limited thereto.

In some embodiments, after the electromagnetic waves L enters the microstructures 280, as the refractive index of the electromagnetic waves L in the microstructures 280 is greater than the refractive index of the electromagnetic waves L in the air, the electromagnetic waves L approach the normal line of the inclined plane 281, forming a first refraction angle θ2 with the normal line of the inclined plane 281. The electromagnetic waves L then pass through the microstructures 280 and are incident on the ceramic layer 210 on the bottom surface of the microstructures 280 in contact with the ceramic layer 210. A second incident angle θ3 of the electromagnetic waves L incident on the ceramic layer 210 may be defined as the angle between the electromagnetic waves L and the normal line of the bottom surface. Next, after the electromagnetic waves L enter the ceramic layer 210, as the refractive index of the electromagnetic waves L in the ceramic layer 210 is greater than the refractive index of the electromagnetic waves L in the ceramic layer 210, the electromagnetic waves L approach the normal line of the bottom surface, forming a second refraction angle θ4 with the normal line of the bottom surface. In some embodiments, the first incident angle θ1 is greater than the first refraction angle θ2, and the second incident angle θ3 is greater than the second refraction angle θ4. With the configuration above, the electromagnetic waves L may be introduced into the ceramic layer 210 by the microstructures 280 to be further absorbed by the ceramic layer 210.

Note that the electromagnetic waves L may travel to the second metal layer 240 after entering the ceramic layer 210 and be reflected by the first surface 211 where the second metal layer 240 is in contact with the ceramic layer 210. Since the refractive index of the electromagnetic waves L in the ceramic layer 210 is greater than the refractive index of the electromagnetic waves L in the ceramic layer 210, the electromagnetic waves are totally reflected at the interface between the microstructures 280 and the ceramic layer 210 and return to the ceramic layer 210. Therefore, the probability that the electromagnetic waves are reflected back into the accommodation space SP may be reduced. With the configuration described above, the microstructures 280 not only increases the area of the ceramic layer 210 for absorbing electromagnetic waves but also makes the electromagnetic waves travel along the ceramic layer 210, thus increasing the effect of the ceramic layer 210 absorbing the electromagnetic waves. In addition, the microstructures 280 may also reduce the probability of the electromagnetic waves being reflected back to the accommodation space SP, thereby further improving the noise reduction and anti-noise effects of the composite structure. The composite structure and the package architecture may also achieve the same effect as the above embodiments.

To sum up, in the composite structure and the package architecture including the same according to an embodiment of the disclosure, as the composite structure includes a ceramic layer that absorbs electromagnetic waves and the first metal layer and the second metal layer on both surfaces of the ceramic layer, the composite structure may reflect external electromagnetic waves besides absorbing electromagnetic waves. As such, the composite structure may have the technical effects of anti-noise and noise reduction, and the influence of electromagnetic noise may be reduced in the accommodation space between the composite structure and the substrate. In addition, as the ceramic layer and the metal layer in the composite structure adopt the direct bonding technology to reduce the thermal resistance between the film layers in the composite structure, the second metal layer can effectively dissipate the heat energy transmitted by the ceramic layer. Therefore, the composite structure may have good heat dissipation effect and electromagnetic wave absorption effect at the same time. In addition, since the thermal expansion coefficient of the ceramic layer may match the thermal expansion coefficient of the chip, the variation difference between the chip and the ceramic layer may be reduced and warpage may be reduced, such that the package architecture becomes more reliable. In addition, the composite structure may also include microstructures to further increase the effect of the ceramic layer absorbing electromagnetic waves. The microstructures may also reduce the probability of electromagnetic waves being reflected back to the accommodation space, further improving the noise reduction and anti-noise effects of the composite structure. Based on the above, the package architecture having the composite structure has good heat dissipation, electromagnetic noise reduction, and good electronic performance and quality.

What is claimed is:

1. A composite structure, comprising:
a ceramic layer, having a first surface and a second surface opposite to each other, suitable for absorbing electromagnetic waves, wherein an absorbance reaction range of the electromagnetic waves by the ceramic layer is 100 MHz to 400 GHz;
a first metal layer, disposed on the second surface, having an opening exposing the second surface, wherein an inner sidewall of the first metal layer surrounds the opening;
a second metal layer, disposed on the first surface, wherein an orthographic projection of the second metal layer on the ceramic layer at least partially overlaps an orthographic projection of the opening on the ceramic layer, and the ceramic layer is disposed between the first metal layer and the second metal layer,
wherein a thickness ratio of the first metal layer to the second metal layer ranges from 1:1 to 1:2, and an area ratio of the first metal layer to the second metal layer ranges from 1:1.2 to 1:4.

2. The composite structure of claim 1, wherein a thermal conductivity of the first metal layer or the second metal layer ranges from 100 W/mK to 600 W/mK.

3. The composite structure of claim 1, wherein a thermal conductivity of the ceramic layer ranges from 1 W/mK to 25 W/mK.

4. The composite structure of claim 1, wherein a thermal expansion coefficient of the ceramic layer is 2×10⁻⁶/° C. to 12×10⁻⁶/° C.

5. The composite structure of claim 1, wherein a material of the ceramic layer comprises ferrite, and the ferrite comprises cubic ferrite, hexagonal ferrite, or orthorhombic ferrite.

6. The composite structure of claim 1, wherein an insertion loss of the electromagnetic waves entering the ceramic layer ranges from −2 dB to −15 dB.

7. The composite structure of claim 1, wherein the ceramic layer has a groove, and a bottom surface of the groove and the second surface have a height difference of 0.05 mm to 0.1 mm.

8. The composite structure of claim 1, further comprising a microstructure disposed on the ceramic layer.

9. The composite structure of claim 8, wherein a material of the microstructure comprises polymer material, oxide, nitride, carbide, carbonitride, or graphite.

10. The composite structure of claim 8, wherein a refractive index of the electromagnetic waves in the microstructure is greater than a refractive index of the electromagnetic waves in the air, and a refractive index of the electromagnetic waves in the ceramic layer is greater than the refractive index of the electromagnetic waves in the microstructure.

11. An encapsulation architecture, comprising:
a substrate;
a composite structure, disposed on the substrate, wherein an accommodation space is formed between the composite structure and the substrate, and the composite structure comprising:
a ceramic layer, having a first surface and a second surface opposite to each other, suitable for absorbing electromagnetic waves, wherein the ceramic layer has a groove, and the groove overlaps the accommodation space;
a first metal layer, disposed on the second surface, having an opening exposing the second surface, wherein an inner sidewall of the first metal layer surrounds the opening; and
a second metal layer, disposed on the first surface, wherein an orthographic projection of the second metal layer on the ceramic layer at least partially overlaps an orthographic projection of the opening on the ceramic layer; and
a chip, disposed on the substrate and located in the accommodation space, and the chip is coupled to the ceramic layer of the composite structure in the groove,
wherein a thermal expansion coefficient of the chip matches a thermal expansion coefficient of the ceramic layer of the composite structure.

12. The package architecture of claim 11, further comprising:
a heat dissipation component, disposed on the second metal layer of the composite structure; and
a package component, disposed on the substrate, and adapted to encapsulate the composite structure,
wherein the composite structure is located between the heat dissipation component and the substrate.

13. The package architecture of claim 11, further comprising:
a thermally conductive material layer, disposed on the ceramic layer, wherein the thermally conductive material layer is disposed in the groove and between the chip and the ceramic layer, and a thermal expansion coefficient of the thermally conductive material layer matches a thermal expansion coefficient of the ceramic layer.

14. The package architecture of claim 13, wherein the thermally conductive material layer comprises thermal paste or solder.

15. The package architecture of claim 11, wherein the ceramic layer has a sealed space, the sealed space is located between the first metal layer and the second metal layer, and the sealed space and the accommodation space are isolated by the ceramic layer.

16. The package architecture of claim 15, further comprising a working fluid disposed in the sealed space.

17. The package architecture of claim 15, further comprising a heat-spreading structure for vapor-liquid phase-changing disposed in the sealed space, wherein the heat-spreading structure comprises a heat pipe or a heat spreader.

18. The package architecture of claim 11, wherein the composite structure further comprises:
a circuit component comprising a first circuit pattern, a second circuit pattern, and a plurality of conductive through holes, wherein the first circuit pattern is electrically connected to the second circuit pattern through the conductive through holes, the second circuit pattern is disposed on the first surface of the ceramic layer, the first circuit pattern is disposed on the second surface opposite to the first surface, and the conductive through holes penetrate the ceramic layer,
wherein a number of the chip is plural, the chip comprises a first chip and a second chip, the first chip is disposed on the substrate and is electrically connected to the first circuit pattern, the second chip is disposed on the ceramic layer and is electrically connected to the second circuit pattern.

19. The package architecture of claim 18, further comprising a heat dissipation component disposed on the ceramic layer, wherein the second chip is located between the first surface and the heat dissipation component.

20. The package architecture of claim 11, further comprising a microstructure disposed on a bottom surface of the groove, wherein an included angle exists between an inclined surface of the microstructure and the bottom surface, and the included angle ranges from 30° to 80°.
